(19) United States
(12) Patent Application Publication
(10) Pub. No.: US 2009/0003065 A1
(43) Pub. Date: Jan. 1, 2009

(54) Flash cell with improved program disturb

(75) Inventor: Andrei Mihnea, Boise, ID (US)

Correspondence Address: FLETCHER YODER (MICRON TECHNOLOGY, INC.), P.O. BOX 692289, HOUSTON, TX, 77269-2289, US

(73) Assignee: Micron Technology, Inc.

(21) Appl. No.: 11/821,915

(22) Filed: Jun. 26, 2007

(51) Int. Cl. H01L 29/788; G11C 11/34; H01L 21/336

(52) U.S. Cl. 365/185.11; 257/316; 438/257; 257/E29.3; 257/E21.409

(57) ABSTRACT

Memory cells, memory arrays, memory devices and methods are disclosed, such as those involving a memory cell comprising a floating gate comprising lightly doped polysilicon, wherein the lightly doped polysilicon has a substantially uniform doping concentration. One such memory cell further comprises a control gate and dielectric disposed between the floating gate and the control gate.

### BACKGROUND

1. Field of the Invention

Embodiments of the present invention relate generally to memory devices and more specifically, in one or more embodiments, to floating-gate memory devices having reduced program and read disturb sensitivity.

2. Description of the Related Art

Processor-based systems, such as computers, typically include one or more memory devices to provide storage capability for the system. System memory is generally provided in the form of one or more integrated circuit chips or devices and generally includes both random access memory (RAM) and read-only memory (ROM). System RAM is typically large and volatile and provides the system's main memory. Static RAM and Dynamic RAM are commonly employed types of random access memory. In contrast, system ROM is generally small and includes non-volatile memory for storing initialization routines and identification information. Electrically erasable read-only memory (EEPROM) is one commonly employed type of read-only memory, wherein an electrical charge may be used to program and/or erase data in the memory.

One type of non-volatile memory that is of particular use is a flash memory. A flash memory is a type of EEPROM that can be erased and reprogrammed in blocks. Flash memory is often employed in personal computer systems in order to store the Basic Input Output System (BIOS) program such that it can be easily updated. Flash memory is also employed in wireless electronic devices because it enables the manufacturer to support new communication protocols as they become standardized and to provide the ability to remotely upgrade the device for enhanced features.

A typical flash memory includes a memory array having a large number of memory cells arranged in rows and columns. The memory cells are generally grouped into blocks such that groups of cells can be programmed or erased simultaneously. Each of the memory cells includes a floating-gate field-effect transistor capable of holding a charge. Floating-gate memory cells differ from standard MOSFET designs in that they include an electrically isolated gate, referred to as the “floating gate,” in addition to the standard control gate. The floating gate is generally formed over the channel and separated from the channel by a dielectric layer. The control gate is formed directly above the floating gate and is separated from the floating gate by another dielectric layer. A floating-gate memory cell stores information by holding electrical charge within the floating gate. By adding or removing charge from the floating gate, the threshold voltage of the cell changes, thereby defining whether this memory cell is programmed or erased.

A NAND flash-memory device is a common type of flash-memory device, so called for the logical form in which the basic memory cell configuration is arranged. Typically, the array of memory cells for NAND flash-memory devices is arranged such that the control gate of each memory cell of a row of the array is connected to a word line. Columns of the array include strings (often termed “NAND strings”) of memory cells connected together in series, source to drain, between a pair of select lines, a source select line and a drain select line. The source select line includes a source select gate at each intersection between a NAND string and the source select line, and the drain select line includes a drain select gate at each intersection between a NAND string and the drain select line. The select gates are typically field-effect transistors. Each source select gate is connected to a source line, while each drain select gate is connected to a column bit line.

The memory array is accessed by a row decoder activating a row of memory cells by selecting the word line connected to a control gate of a memory cell. In addition, the word lines connected to the control gates of unselected memory cells of each string are driven to operate the unselected memory cells as pass transistors, so that they pass current in a manner that is unrestricted by their stored data values. Current then flows from the source line to the bit line through each NAND string via the corresponding select gates, restricted only by the selected memory cells of each string. This places the current-encoded data values of the selected memory cells on the bit lines.

While floating-gate memory devices have gained widespread acceptance, a number of data-retention failures impact their reliability. “Disturbs” are one type of data-retention failure that impacts the reliability of floating-gate memory devices. In general, disturbs occur when a read, program, or erase operation causes an unintended change in the threshold voltage of one or more memory cells in the array. For instance, a program disturb occurs when one or more memory cells are unintentionally programmed, while programming other memory cells in the array. In a similar manner, a read disturb occurs when one or more memory cells are unintentionally programmed during a read operation.

Embodiments of the present invention may be directed to one or more of the problems set forth above.

### BRIEF DESCRIPTION OF THE DRAWINGS

FIG. 1 illustrates a block diagram of a processor-based device having a memory that includes memory devices configured in accordance with one or more embodiments of the present invention;

FIG. 2 illustrates a block diagram of a memory device having a memory array configured in accordance with one or more embodiments of the present invention;

FIG. 3 is schematic diagram of a NAND flash-memory array having memory cells configured in accordance with one or more embodiments of the present invention;

FIG. 4 illustrates a cross-sectional view of a floating gate memory device in accordance with one or more embodiments of the present invention;

FIG. 5 is a graph illustrating read-disturb time for various polysilicon doping concentrations;

FIG. 6 is a graph illustrating programming time for various polysilicon doping concentrations; and

FIG. 7 is a flow chart illustrating a method of fabricating floating-gate memory cells in accordance with one or more embodiments of the present invention.

### DETAILED DESCRIPTION OF SPECIFIC EMBODIMENTS

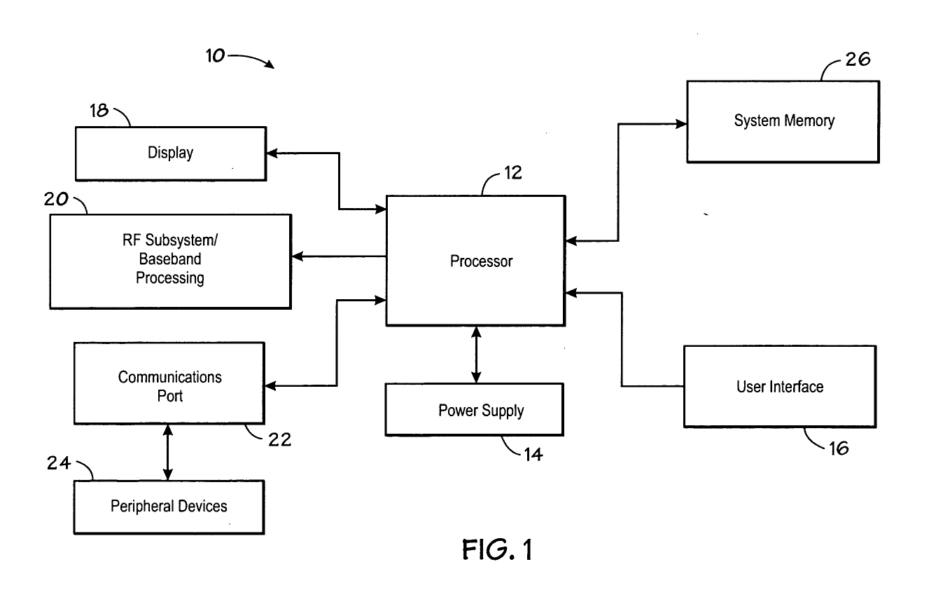

Turning now to the drawings, and referring initially to FIG. 1, a block diagram depicting a processor-based system, generally designated by reference numeral 10, is illustrated. The system 10 may be any of a variety of types such as a computer, pager, cellular phone, personal organizer, control circuit, etc. In a typical processor-based system, a processor 12, such as a microprocessor, controls the processing of system functions and requests in the system 10. Further, the processor 12 may comprise a plurality of processors that share system control.

The system 10 typically includes a power supply 14. For instance, if the system 10 is a portable system, the power supply 14 may advantageously include permanent batteries, replaceable batteries, and/or rechargeable batteries. The power supply 14 may also include an AC adapter, so the system 10 may be plugged into a wall outlet, for instance. The power supply 14 may also include a DC adapter such that the system 10 may be plugged into a vehicle cigarette lighter, for instance.

Various other devices may be coupled to the processor 12 depending on the functions that the system 10 performs. For instance, a user interface 16 may be coupled to the processor 12. The user interface 16 may include buttons, switches, a keyboard, a light pen, a mouse, and/or a voice recognition system, for instance. A display 18 may also be coupled to the processor 12. The display 18 may include an LCD display, a CRT, LEDs, and/or an audio display, for example.

Furthermore, an RF sub-system/baseband processor 20 may also be coupled to the processor 12. The RF sub-system/baseband processor 20 may include an antenna that is coupled to an RF receiver and to an RF transmitter (not shown). A communications port 22 may also be coupled to the processor 12. The communications port 22 may be adapted to be coupled to one or more peripheral devices 24 such as a modem, a printer, a computer, or to a network, such as a local area network, remote area network, intranet, or the Internet, for instance.

Because the processor 12 controls the functioning of the system 10 by implementing software programs, the system 10 uses memory to enable the processor 12 to be efficient. Generally, the memory is coupled to the processor 12 to store and facilitate execution of various programs. For instance, the processor 12 may be coupled to system memory 26, which may include volatile memory, such as Dynamic Random Access Memory (DRAM) and/or Static Random Access Memory (SRAM). The system memory 26 may also include non-volatile memory, such as read-only memory (ROM), EEPROM, and/or flash memory to be used in conjunction with the volatile memory. As described further below, the system memory 26 may include one or more memory devices, such as flash-memory devices, that may include a floating-gate memory array fabricated in accordance with embodiments of the present invention.

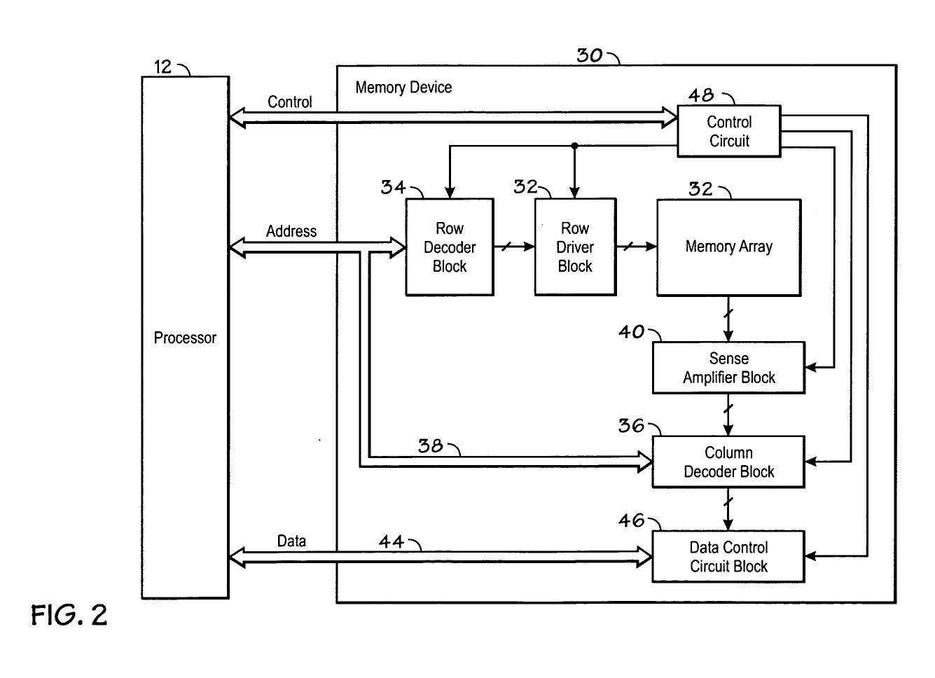

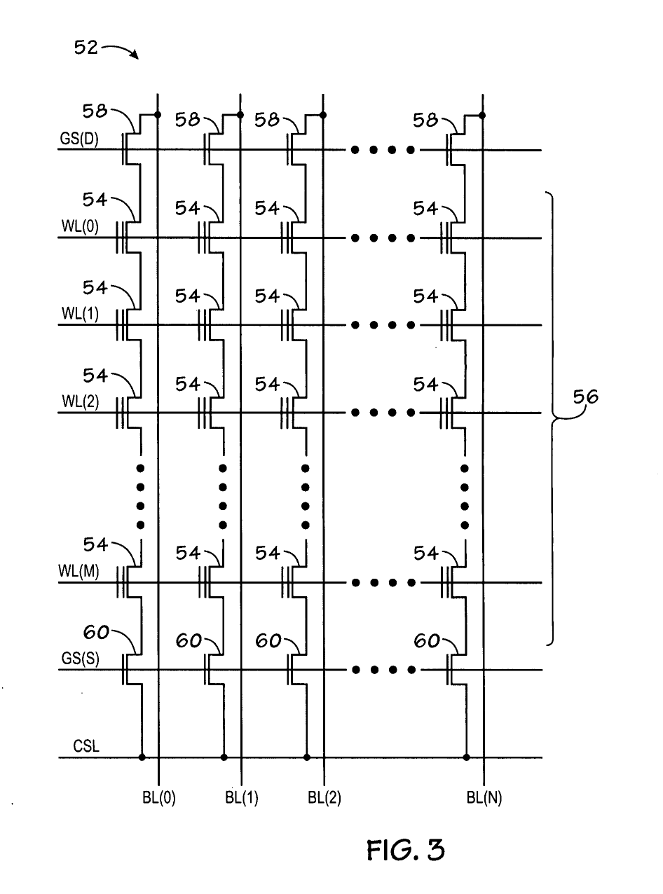

FIG. 2 is a block diagram illustrating a flash-memory device 30 that may be included as a portion of the system memory 26 of FIG. 1. As will be described further below with respect to FIG. 3, the flash-memory device 30 may be a NAND flash-memory device. The flash-memory device 30 generally includes a memory array 32. The memory array 32 generally includes many rows and columns of conductive traces arranged in a grid pattern to form a number of memory cells. The rows or “row lines” that make up the memory array 32 are generally referred to as “word lines.” The columns or “column lines” are generally referred to as “bit lines” or “digit lines.” The size of the memory array 32 (i.e., the number of memory cells) will vary depending on the size of the flash-memory device 30.

To access the memory array 32, a row decoder block 34 and a column decoder block 36 are provided and are configured to receive and translate address information from the processor 12 via the address bus 38 to access a particular memory cell in the memory array 32. A sense amplifier block 40 having a plurality of sense amplifiers is also provided between the column decoder block 36 and the memory array 32 to sense and amplify individual values stored in the memory cells. Further, a row driver block 42 is provided between the row decoder block 34 and the memory array 32 to activate selected word lines in the memory array according to a given row address.

During read and write operations, data may be transferred to and from the flash-memory device 30 via the data bus 44. The coordination of the data and address information may be conducted through a data control circuit block 46. Finally, the flash-memory device 30 may include a control circuit 48 configured to receive control signals from the processor 12 via the control bus 50. The control circuit 48 is coupled to each of the row decoder block 34, the column decoder block 36, the sense amplifier block 40, the row driver block 42 and the data control circuit block 46, and is generally configured to coordinate timing and control among the various circuits in the flash-memory device 30. During program, program-verify, and read operations, the control circuit 48 is configured to control the values of voltages applied to word and bit lines. The control circuit 48 may include any suitable type of controller, including a state machine, a sequencer, etc., for example.

FIG. 3 illustrates an embodiment of the memory array 32 of FIG. 2. In the present embodiment, the memory array 32 comprises a NAND memory array 52. The NAND memory array 52 includes word lines WL(0)-WL(M) and intersecting bit lines BL(0)-BL(N). As will be appreciated, for ease of addressing in the digital environment, the number of word lines WL and the number of bit lines BL are each a power of two (e.g., 256 word lines WL by 4,096 bit lines BL). The NAND cell strings may be coupled to the bit lines BL(0)-BL(N) in a many-to-one relationship.

The NAND memory array 52 includes a floating-gate transistor 54 located at each intersection of a word line WL and a bit line BL. The floating-gate transistors 54 serve as non-volatile memory cells for storage of data in the NAND memory array 52, as previously described. As will be appreciated, each floating-gate transistor 54 includes a source, a drain, a floating gate, and a control gate. The control gate of each floating-gate transistor 54 is coupled to a respective word line WL. The floating-gate transistors 54 are connected in series, source to drain, to form a NAND string 56 formed between gate select lines. Specifically, the NAND strings 56 are formed between the drain select line GS(D) and the source select line GS(S). The drain select line GS(D) is coupled to each NAND string 56 through a respective drain select gate 58. Similarly, the source select line GS(S) is coupled to each NAND string 56 through a respective source select gate 60. The drain select gates 58 and the source select gates 60 may each comprise a field-effect transistor (FET), for instance. A column of the memory array 52 includes a NAND string 56 and the source select gate 60 and drain select gate 58 connected thereto. A row of the floating-gate transistors 54 are those transistors commonly coupled to a given word line WL.

The source of each source select gate 60 is connected to a common source line CSL. The drain of each source select gate 60 is coupled to the source of the first of the floating-gate transistors 54 in a respective NAND string 56. The gate of each source select gate 60 is coupled to the source select line GS(S).

The drain of each drain select gate 58 is connected to a respective bit line BL for the corresponding NAND string 56. The source of each drain select gate 58 is connected to the drain of the last of the floating-gate transistors 54 of a respective NAND string 56. Accordingly, as illustrated in FIG. 3, each NAND sting 56 is coupled between a respective drain select gate 58 and source select gate 60. The gate of each drain select gate 58 is coupled to the drain select line GS(D).

As previously described, one type of data-retention failure commonly referred to as a “disturb” occurs when a read, program, or erase operation causes an unintended change in the threshold voltage of one or more memory cells in a floating gate memory array, such as the floating-gate transistors 64A-64C of the structure 62. A program disturb occurs when one or more memory cells are unintentionally programmed, while programming other memory cells in the array. For instance, referring again to FIG. 3, a floating-gate transistor 54 on the bit line BL1 will also experience a high electric field between the floating gate and the channel when programming another one of the floating-gate transistors 54 on bit line BL1. This may cause electrons to tunnel from the channel to the floating gate, leading to a changed threshold voltage. Another disturb that may impact data retention is a read disturb, wherein when one or more memory cells are unintentionally programmed during read operations. With reference to FIG. 3, the floating gate transistors 54 on an unselected word line (such as WL(1)) may experience a high electric field between the floating gate and the channel when reading one of the floating-gate transistors 54 on a different word line, for instance.

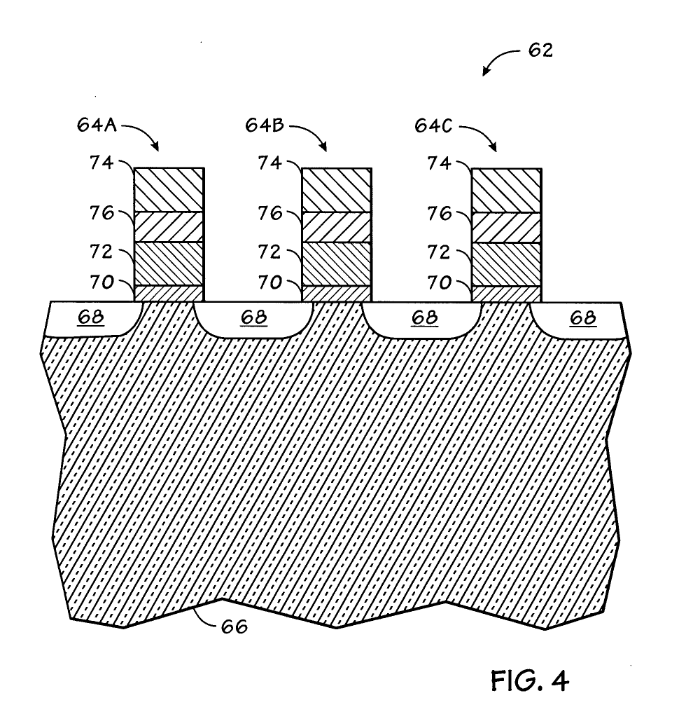

One or more embodiments of the present invention may reduce the disturb sensitivities of the floating-gate transistors 54 by using a lightly doped polysilicon floating gate. As will be described in more detail below with respect to FIG. 4, the polysilicon floating gate of the floating-gate transistors is lightly doped, for example, having a doping concentration of less than or equal to about 5×10¹⁸ atoms per cm³.

Turning briefly to FIG. 4, a cross-sectional view of a portion of a floating-gate memory array, such as a NAND memory array, is illustrated and generally designated by reference numeral 62. The structure 62 illustrates a cross-sectional view of three floating-gate transistors 64A-64C, taken along the bit line BL of a floating gate memory array. The structure 62 comprises a substrate 66, which may comprise silicon or gallium oxide, for example. The substrate 66 may contain doped diffusion regions 68 to provide the source and drain of the floating-gate transistors 64A-64C. Each floating-gate transistor 64A-64C generally includes a gate oxide 70, such as silicon dioxide (SiO2), formed over the substrate 66. As will be appreciated, in certain embodiments, the diffusion regions 68 for each of the floating-gate transistors 64A-64C may be omitted. For instance, a single gate oxide 70 may extend under each floating-gate transistor 64A-64C from the drain select gate to the source select gate with or without intervening diffusion regions 68.

Each floating gate transistor 64A-64C also includes an isolated floating gate 72. In the illustrated embodiment, each floating gate 72 is formed over the gate oxide 70 and between a pair of the diffusion regions 68. As will be appreciated, the polysilicon layer forming each floating gate 72 is typically doped with a conductivity-enhancing impurity, such as phosphorous. For instance, the polysilicon layer may be undoped as formed and then doped (e.g., through ion implantation) with the conductivity-enhancing impurity. Conventionally, the floating gate 72 has been heavily doped (e.g., having a doping concentration of at least 2×10¹⁹ atoms per cm³) to increase the conductivity of the polysilicon forming the floating gate 72. However, in accordance with one or more embodiments of the present invention, the floating gates 74 are lightly doped, such as to reduce the disturb sensitivities of the floating-gate transistors 64A-64C. In certain embodiments, the floating gate 72 may be lightly doped to have a substantially uniform doping concentration. Surprisingly, it has been recently discovered that a doping concentration in a range from about 1×10¹⁸ atoms per cm³ to about 5×10¹⁸ atoms per cm³ is believed to provide reduced disturb sensitivities while having little effect on programming efficiency. In certain embodiments, the floating gate has a doping concentration in a range from about 1×10¹⁸ atoms per cm³ to about 3×10¹⁸ atoms per cm³. As will be appreciated, doping concentrations below 1×10¹⁸ atoms per cm³ may result in undesirable slow formation of inversion on the floating gate 72.

Each floating-gate transistor 64A-64C further includes a control gate 74, which may be formed of a conductive layer, such as polysilicon. As will be appreciated, because of the configuration and operation of the array, each of the floating-gate transistors 64A-64C in a single word line WL may share a common control gate 74. The floating gates 72 and control gate 74 are electrically isolated from one another by an inter-gate dielectric layer 76. The inter-gate dielectric layer may comprise SiO₂ or SiNₓ, for example.

As will be appreciated, voltage will be applied to the control gate 74 of a floating-gate transistor 64A-64C during its operation. Some of this voltage applied to the control gate 74 may be dissipated due to poly-depletion effects. Poly-depletion generally refers to the formation of a quasi-dielectric material (or depletion region) in the gate material due to the electric field applied across the gate. Poly-depletion is generally a function of the doping concentration. For higher doping concentrations of the polysilicon floating-gate 72, the depletion region is smaller such that less voltage is dropped across the floating gate 72. For lower doping concentrations, the depletion region is larger such that more voltage is dropped across the floating gate 72.

As described above, conventional floating gates have typically been heavily doped such that less voltage is dropped across the floating gate, thereby making the floating gate more conductive. However, as described above, the floating gate 72 can be lightly doped to reduce the disturb sensitivities of the floating-gate transistors 64A-64C. As previously described, more voltage should be dropped across the lightly doped floating gate 72 due to a larger depletion region. This larger depletion region should result in less of the voltage applied to the control gate 74 being applied to the gate oxide 70 due to more voltage dissipation in the floating gate 72. As will be appreciated, a lower applied voltage to the gate oxide 70 is less likely to trigger electron tunneling or injection into the floating gate 72, resulting in a decreased likelihood of an unintended change in threshold voltage. In addition, the lightly doped floating gate 72 should have similar poly-depletion effects during read and program operations. In this manner, the poly-depletion effects of the lightly doped floating gate 72 may be utilized to reduce the disturb sensitivities of the floating-gate transistors 64A-64C. However, even though the larger depletion region results in more voltage drop, the lightly doped floating gate 72 should have negligible impact on programming efficiency.

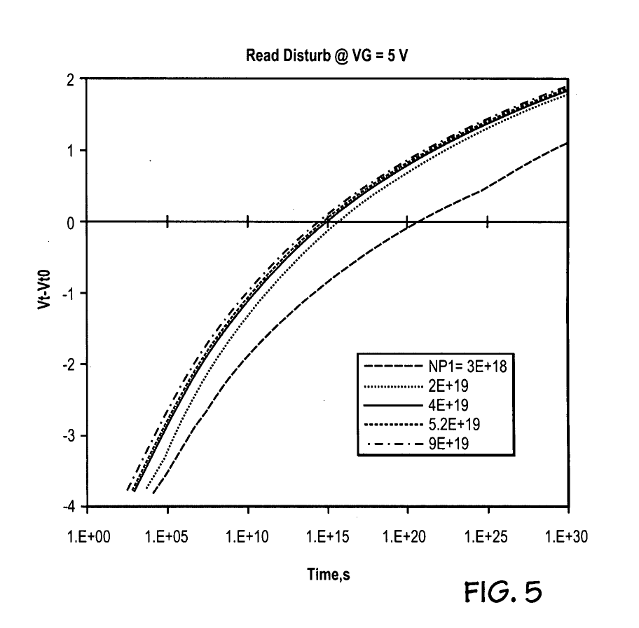

FIG. 5 illustrates the results of a computer simulation of read disturb as a function of the floating-gate doping concentration. More particularly, FIG. 5 is a graphical illustration of read disturb by Fowler-Nordheim tunneling at a control-gate voltage of 5V for a NAND memory cell. A 50 nm NAND memory cell was used for this simulation. In the graphical illustration, a read disturb occurs when the floating gate charge induced variation of cell threshold voltage Vₜ-Vₜ₀ crosses zero. As illustrated, the time for read disturb is generally the same for each doping concentration except for the lowest doping concentration of 3×10¹⁸ atoms per cm³. For instance, the lowest doping concentration of 3×10¹⁸ atoms per cm³ took approximately 1×10²⁰ seconds for read disturb to occur, while read disturb occurred for the higher doping concentrations at approximately 1×10¹⁵ seconds. Accordingly, this simulation illustrates that the disturb sensitivities of a memory cell may be reduced by using a floating gate having a doping concentration in the range of from about 1×10¹⁸ atoms per cm³ to about 5×10¹⁸ atoms per cm³.

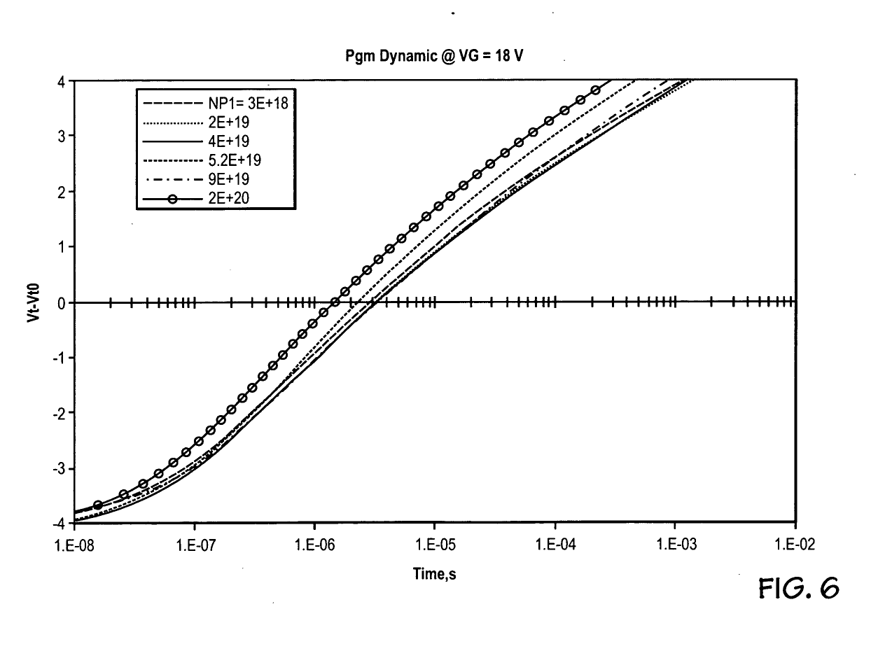

Further, as described above, use of a lightly doped polysilicon floating gate should have little impact on the programming efficiency of a memory cell while providing reduced disturb sensitivities. FIG. 6 illustrates the results of a computer simulation of program dynamic as a function of the floating-gate doping concentration. More particularly, FIG. 6 is a graphical illustration of the program dynamic at a control-gate voltage of 18V for a 50 nm NAND memory cell. As expected, FIG. 6 illustrates that the programming efficiency (i.e., the program time to any fixed threshold voltage variation Vₜ-Vₜ₀) is faster for the highest doping concentrations. Surprisingly, however, suitable program times were still achieved for the lightly doped polysilicon floating gate having a doping concentration of 3×10¹⁸ atoms per cm³ . For instance, a threshold voltage variation Vₜ-Vₜ₀ of at least 1V was achieved for each doping concentration in no more than approximately 10 μs. Accordingly, this simulation illustrates that the disturb sensitivities of a memory cell may be reduced by using a floating gate having a doping concentration in the range of from about 1×10¹⁸ atoms per cm³ to about 5×10¹⁸ atoms per cm³.

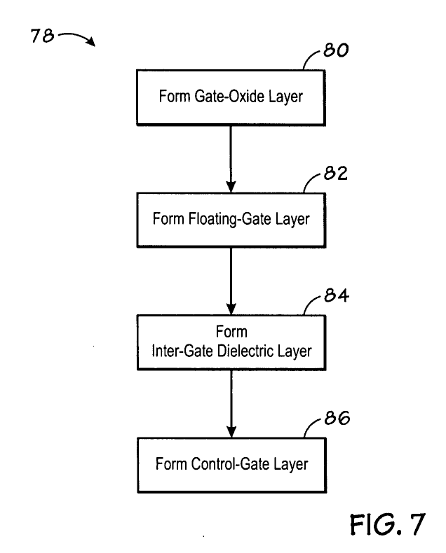

As will be appreciated, any suitable technique may be utilized to fabricate floating-gate transistors having a lightly doped floating gate, in accordance with embodiments of the present invention. FIG. 7 illustrates a process 78 in accordance with one embodiment of the present invention. As indicated in block 80, a gate-oxide layer is formed (e.g., disposed or grown) on a substrate. The substrate may comprise silicon or gallium arsenide, for example. The gate-oxide layer may comprise silicon dioxide (SiO₂), for example. After forming the gate-oxide layer, a floating-gate layer is formed over the gate-oxide layer, as indicated in block 82. As previously discussed, the floating-gate layer may comprise lightly doped polysilicon. In certain embodiments, the polysilicon may be undoped as formed and then doped (e.g., through ion implantation) with the appropriate conductivity-enhancing impurity. The floating-gate layer will be used to form the floating gates of individual transistors. After deposition of the floating-gate layer, an inter-gate dielectric layer is formed over the floating-gate layer, as indicated in block 84. The inter-gate dielectric layer may comprise SiO₂ or SiNₓ, for example. As indicated in block 86, a control-gate layer is then formed over the inter-gate dielectric layer. The control-gate layer may be formed of a conductive material, such as polysilicon. As will be appreciated, any suitable mask and etch process may be used to form the individual memory cells (such as floating-gate transistors 64A-64C on FIG. 4) in the above-described layers. Moreover, those of ordinary skill in the art will appreciate that the process 78 may include a variety of different intermediate steps in the fabrication of the floating-gate transistors.

While embodiments of the invention may be susceptible to various modifications and alternative forms, specific embodiments have been shown by way of example in the drawings and have been described in detail herein. However, it should be understood that the invention is not intended to be limited to the particular forms disclosed. Rather, embodiments of the invention are to cover all modifications, equivalents, and alternatives falling within the spirit and scope of these embodiments, as defined by the following appended claims.

What is claimed is:

1. A memory cell comprising:
a floating gate comprising polysilicon, wherein the polysilicon is lightly doped and has a substantially uniform doping concentration;
a control gate; and
dielectric disposed between the floating gate and the control gate.

2. The memory cell of claim 1, wherein the polysilicon has a doping concentration in a range from about 1×10¹⁸ to about 5×10¹⁸ atoms per cubic centimeter.

3. The memory cell of claim 1, wherein the polysilicon has a doping concentration of in a range of from about 1×10¹⁸ to 3×10¹⁸ atoms per cubic centimeter.

4. The memory cell of claim 1, wherein the control gate comprises polysilicon.

5. A memory device comprising:
a plurality of memory cells, wherein each memory cell comprises:
a floating gate comprising lightly doped polysilicon, wherein the lightly doped polysilicon has a substantially uniform doping concentration;
a control gate; and
dielectric disposed between the floating gate and the control gate.

6. The memory device of claim 5, wherein the doping concentration of the lightly doped polysilicon of each memory cell is in a range from about 1×10¹⁸ to about 5×10¹⁸ atoms per cubic centimeter.

7. The memory device of claim 5, wherein the memory cells are arranged in NAND strings.

8. The memory device of claim 7, wherein each string of the memory cells has a source select gate at one end of the string and a drain selected gate at another end of the string.

9. The memory device of claim 5, comprising a diffusion region between each memory cell.

10. The memory device of claim 5, comprising a control circuit configured to control application of voltage to the memory cells.

11. The memory device of claim 5, wherein the floating gate is configured to have a depletion region during application of a voltage to the control gate that dissipates the voltage such that a read-disturb time is longer compared with no floating-gate depletion in read.

12. A memory array comprising:
a substrate; and
a plurality of memory cells formed over the substrate, each memory cell comprising:
a gate dielectric formed over the substrate;
a floating gate comprising polysilicon having a substantially uniform doping concentration of in a range of from about 1×10¹⁸ to about 5×10¹⁸ atoms per cubic centimeters, formed over the gate dielectric layer;
an inter-gate dielectric formed over the polysilicon; and
a conductive material formed over the inter-gate dielectric.

13. The memory array of claim 12, wherein the memory cells are arranged in a NAND configuration.

14. The memory array of claim 12, wherein the conductive material formed over the inter-gate dielectric comprises polysilicon.

15. The memory array of claim 12, comprising a diffusion region between each memory cell.

16. A system, comprising:
a processor; and
a memory sub-system operatively coupled to the processor and comprising a flash-memory device, wherein the flash-memory device comprises a plurality of memory cells arranged in a plurality of rows and columns, wherein each memory cell comprises:
a floating gate comprising a doped polysilicon layer, wherein the doped polysilicon layer has a substantially uniform doping concentration of less than or equal to about 5×10¹⁸ atoms per cubic centimeter;
a control gate; and
an inter-gate dielectric layer disposed between the floating gate and the control gate.

17. The system of claim 16, wherein the doping concentration of the doped polysilicon layer is from about 1×10¹⁸ to about 5×10¹⁸ atoms per cubic centimeter.

18. The system of claim 16, wherein the system is a computer, a pager, a cellular phone, a personal organize, or a control circuit.

19. A method of forming a floating-gate memory array comprising:
forming a gate-oxide layer on a substrate;
forming a floating-gate layer over the gate-oxide layer, wherein the floating-gate layer comprises a polysilicon layer that is lightly doped and has a substantially uniform doping concentration;
forming a dielectric layer over the floating-gate layer; and
forming a conductive layer over the dielectric layer.

20. The method of claim 19, wherein forming the floating-gate layer comprises forming the polysilicon layer, and doping the polysilicon layer to have a doping concentration in a range from about 1×10¹⁸ to about 5×10¹⁸ atoms per cubic centimeter.
